(19) United States
(12) Patent Application Publication
(10) Pub. No.: US 2013/0319465 A1
(43) Pub. Date: Dec. 5, 2013

(54) METHOD AND SYSTEM FOR RAPID MIXING OF PROCESS CHEMICALS USING AN INJECTION NOZZLE

(71) Applicant: TOKYO ELECTRON LIMITED, Tokyo (JP)

(72) Inventor: Ian J. Brown, Austin, TX (US)

(73) Assignee: TOKYO ELECTRON LIMITED, Tokyo (JP)

(21) Appl. No.: 13/632,477

(22) Filed: Oct. 1, 2012

Related U.S. Application Data
(60) Provisional application No. 61/654,938, filed on Jun. 3, 2012.

(51) Int. Cl. B01F 5/04; G03F 7/42; B08B 3/08

(52) U.S. Cl. 134/18; 366/167.1; 366/173.2; 134/115 R; 510/176

(57) ABSTRACT

A method and system for rapidly mixing process chemicals are provided. The method includes injecting a second process chemical into a first process chemical at or near the center of the flow stream, in a flow direction that is the same or different from the flow of the first process chemical, to produce uniform mixing within a target mixing distance and target mixing time. The system includes a first process chemical supply line, a second process chemical supply line, and one or more nozzles configured to produce uniform mixing within a target mixing distance and target mixing time.

### CROSS-REFERENCE TO RELATED APPLICATIONS

Pursuant to 37 C.F.R. §1.78(a)(4), this application claims the benefit of and priority to prior filed co-pending Provisional Application Serial No. 61/654,938 filed Jun. 3, 2012, which is expressly incorporated herein by reference.

### FIELD OF THE INVENTION

This invention relates to methods and systems for mixing of chemicals for use in semiconductor processing.

### BACKGROUND OF THE INVENTION

The removal of resist coatings is a critical process in semiconductor manufacturing and has historically been performed in a batch type processing mode with 25 to 100 wafers being immersed in a mixture of sulfuric acid and peroxide (SPM) for up to 20 minutes. As semiconductor devices shrink in size, defectivity is a significant challenge. To address the high defectivity associated with batch processing, industry focus has switched to developing and using single wafer type processes.

For many reasons, both economic and technical, single wafer SPM processes operate at higher temperatures (170°-220° C.) than batch processes (120°-150° C.). To make single wafer SPM processing economically feasible, the resist strip time must be reduced from 10 minutes to ideally less than 2 minutes. This can be achieved with the higher process temperatures.

High dose ion implant resist strip (HDIRS) is also a driving factor for high temperature single wafer SPM processing, as the crust created when the photoresist is bombarded by high-energy ions is notoriously difficult to remove. A key advantage for single wafer processing is that higher temperatures can be utilized to strip resist coatings. Higher process temperatures have been shown to significantly improve resist strip performance for higher dosed resists (e.g. 1×10¹⁴ atoms/cm²).

One disadvantage of using higher temperature SPM is that material selection for processing chamber materials is restricted to those that would be stable in contact with 220° C. SPM. Another disadvantage is that significant silicon nitride and silicon dioxide film loss is measured at temperatures above 170° C. Typically, the process should strip photoresist without any loss of silicon nitride (Si₃N₄) or silicon dioxide (SiO₂).

Yet another disadvantage is the high level of mist generation in the process chamber. This is a challenge to make multi-chemical processing possible. SPM processing is typically followed by a Standard Clean 1 (SC1) step to remove residual particles from the wafer. The presence of SPM mist during a SC1 process creates a defectivity challenge due to the two chemicals forming an undesirable precipitate that could be deposited on the wafer, e.g., H₂SO₄+NH₄OH=NH₄SO₄+H₂O.

A significant difference between batch and single wafer SPM processing is the time scale. In a wet bench injection, mixing of hydrogen peroxide into sulfuric acid can occur over periods of minutes and the wafer cleaning process can take from 5 to 20 minutes. In contrast, in a single wafer tool, the hydrogen peroxide is injected into and mixed with the sulfuric acid in less than a couple of seconds and in some designs, time periods of less than 5 ms. In a single wafer tool, cleaning times on the wafer are less than 2 minutes, for example, about 30 seconds. The shorter time scale makes the single wafer tool performance more sensitive to the method of how the hydrogen peroxide is injected into the sulfuric acid.

There is thus a need for improved injection of hydrogen peroxide liquid into the sulfuric acid in a single wafer SPM process.

### SUMMARY OF THE INVENTION

A method for rapidly mixing process chemicals to generate a treatment liquid for processing a single substrate is provided. The method comprises flowing a first process chemical in a process chemical delivery system with a first direction of flow having a center axis, and injecting a second process chemical from a nozzle into the flow of the first process chemical in the process chemical delivery system to effect a mixing of the first process chemical with the second process chemical to form a treatment liquid. The nozzle is oriented at or near the center axis to produce uniformity in the mixing of the first and second process chemicals within a target mixing distance between the nozzle and an outlet of the process chemical delivery system and within a target mixing time.

Additionally, a system for mixing of process chemicals to optimize resist strip performance is provided. The system includes a process chamber containing a single substrate, where the substrate has a high dose ion implant resist strip and the process chamber is configured to strip the resist, and a process chemical delivery system configured to deliver a treatment liquid comprising a first process chemical, a second process chemical, and reaction products of the first and second process chemicals from an outlet onto a portion of the surface of the substrate. The process chemical delivery system comprises a first process chemical supply line configured to deliver the first process chemical at a first temperature, a first flow rate, and a first direction of flow, and a second process chemical supply line configured to deliver the second process chemical at a second temperature and a second flow rate, the second process chemical supply line having an injection tube with a nozzle arrangement that includes at least one nozzle positioned to inject the second process chemical in the center of flow of the first process chemical in the first process chemical supply line. The first process chemical supply line, the second process chemical supply line, and the nozzle arrangement are operably configured to complete uniform mixing of the first and second process chemicals within the first process chemical supply line along a target mixing distance between the nozzle arrangement and the outlet and within a target mixing time.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention.

FIG. 1 is a schematic depicting the reaction process of combining hydrogen peroxide and sulfuric acid to produce Caro's acid.

FIG. 2A is a graph illustrating poor mixing efficiency within a mixing zone when Caro's acid is produced by utilizing a t-junction.

FIG. 2B shows a partial cross sectional view of a t-junction.

FIG. 3A is a cross sectional view of an embodiment of a center injection junction.

FIG. 3B is a graph illustrating improved mixing efficiency when Caro's acid is produced by utilizing a center injection junction.

FIG. 4A is a perspective view showing a coaxial, counter-flow, center injection configuration.

FIG. 4B is a perspective view of a perpendicularly joined, center injection configuration.

FIG. 4C is a perspective view of a perpendicularly joined, center injection configuration, illustrating various locations and configurations of nozzles from a single injection tube.

FIG. 4D is a perspective view showing a coaxial, same direction flow, center injection configuration.

FIG. 5 is a cross sectional view, taken along line 5-5 on FIG. 4A, that illustrates disposing a nozzle at an offset-distance from the center of a fluid flow.

### DETAILED DESCRIPTION

During certain steps of semiconductor wafer processing, Caro's Acid, a solution of sulfuric acid and hydrogen peroxide, is utilized to remove photoresist or organic contaminants. Because of its inherent instability, Caro's Acid is often prepared immediately prior to use. In certain applications, it is prepared by mixing sulfuric acid and hydrogen peroxide, in-situ, as the solution is dispensed from an outlet of a small diameter tube (typically ¼ inch). More specifically, hydrogen peroxide is often injected perpendicularly into the flowing sulfuric acid using a simple t-junction. However, a t-junction is not an efficient method to uniformly mix hydrogen peroxide into the sulfuric acid, since the t-junction introduces the hydrogen peroxide into a relatively low velocity and low turbulence region of the sulfuric acid flow. This inefficient mixing is particularly problematic during single wafer processing operations, wherein the goal is to ensure that the hydrogen peroxide is properly mixed into the sulfuric acid in the shortest time possible.

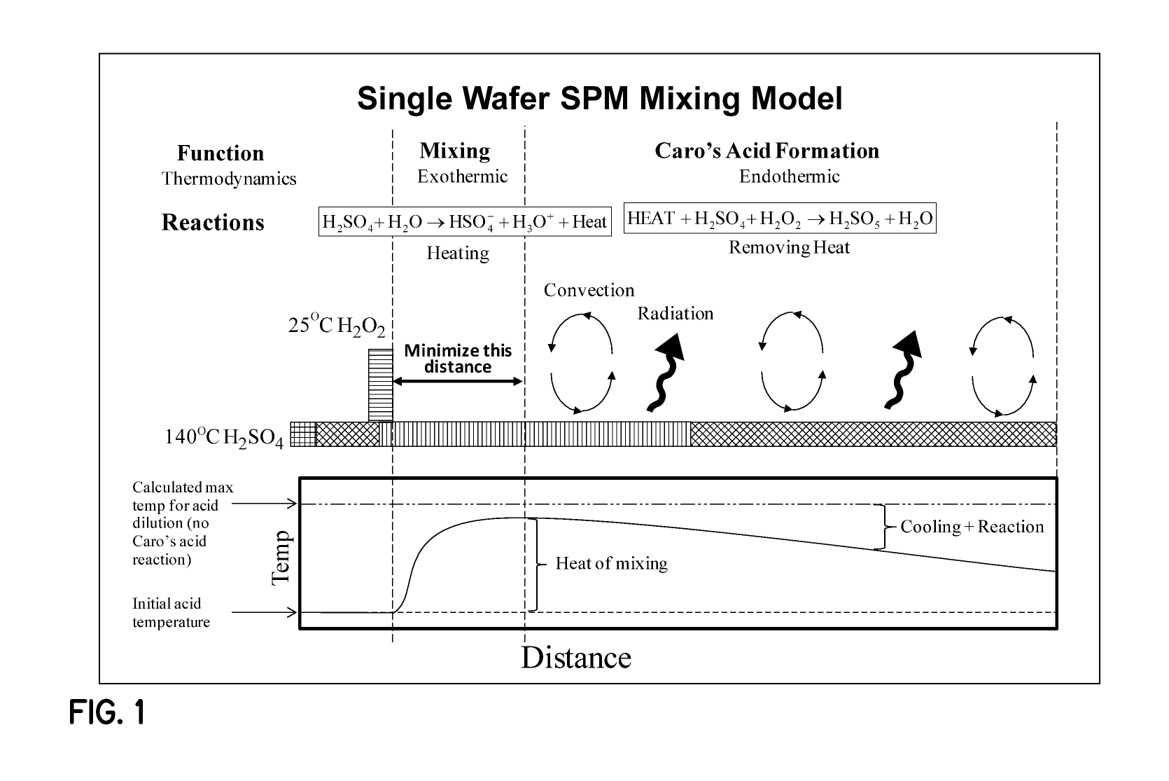

FIG. 1 is a schematic illustrating the processes that occur during and after injection of hydrogen peroxide into sulfuric acid. Rapid mixing of hydrogen peroxide into sulfuric acid is important to achieve high yield conversion of hydrogen peroxide into Caro's acid, which is necessary for efficient and rapid removal of photoresist. Additionally, rapid injection and complete mixing of hydrogen peroxide into sulfuric acid provides more time (and consequently higher conversion) for the chemical reaction between hydrogen peroxide and sulfuric acid to form Caro's acid prior to dispensing onto the resist coated substrate.

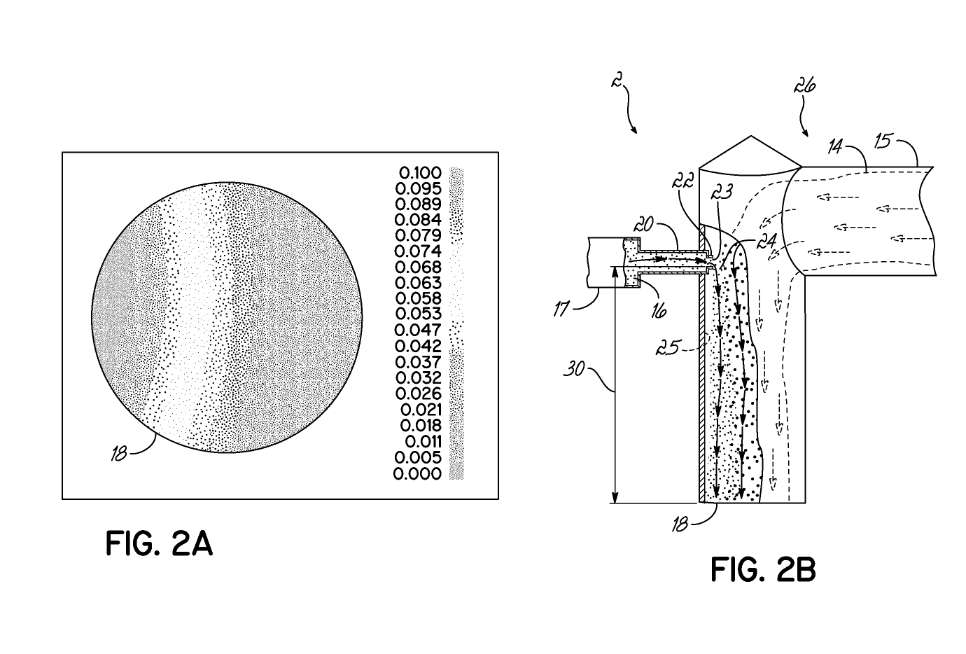

For wet bench applications, mixing times of 2-5 minutes can be tolerated. For single wafer tools, mixing times of 1-2 ms are advantageous. As depicted in FIG. 2A and 2B, simulated mixing results for a standard t-junction type injection system 2 show the concentration of hydrogen peroxide 16 carried in a hydrogen peroxide fluid line 17 after injection into sulfuric acid 14 carried in a sulfuric acid fluid line 15. In particular, the illustration of FIG. 2A shows that the hydrogen peroxide 16 is not uniformly mixed at the outlet 18. In this standard t-junction type injection system 2 as shown in FIG. 2B, the injection tube 20 and its nozzle 22 and corresponding nozzle exit 23 are configured to create a mixing zone 24 that is localized near the interior wall 25 of the process chemical delivery system 26. Uniformity throughout the delivery system 26 is not obtained at any point along the mixing distance 30, such that a non-uniform fluid exits the delivery system 26 at outlet 18. Stiffing

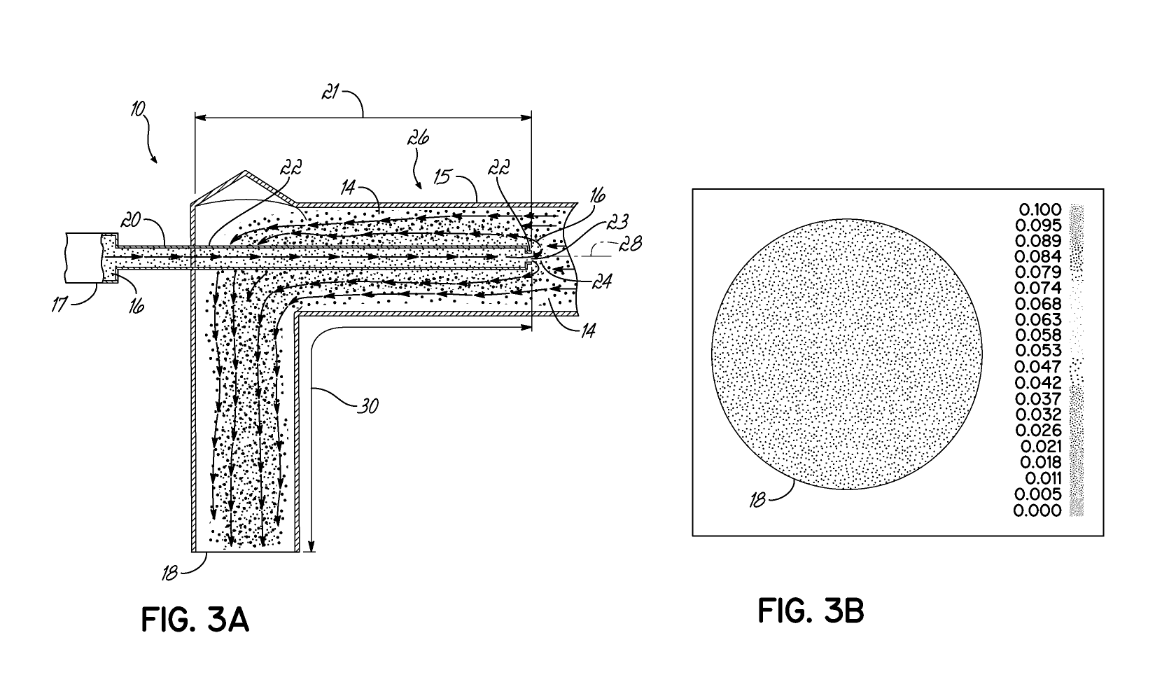

To address the non-uniformity in mixing, and in accordance with the invention, one embodiment of a chemical mixing system 10 is configured as shown in FIG. 3A. This embodiment provides an injection tube 20 and nozzle 22 that is designed to inject hydrogen peroxide 16 from the nozzle exit 23 coaxially into the center 28 of the sulfuric acid 14 flow stream, in a counter-flow direction. It should be noted, as additional figures will illustrate, that injection need not be restricted to center or coaxial embodiments, or to counter-flow. For example, perpendicular injection into a region of the sulfuric acid 14 other than the center 28 may produce satisfactory results. Additionally, other non-parallel angles of approach are beneficial in certain environments.

Injecting at the center 28 of the process chemical delivery system 26 (i.e., along a center axis of the flow stream) is advantageous because it introduces hydrogen peroxide 16 into a mixing zone 24, that utilizes the region of highest fluid velocity (i.e., as a result of frictional forces against a container wall, the center of a column of moving fluid has a higher velocity relative to the perimeter of the column of fluid). Also, the injection tube 20, itself, creates localized disturbances in the flow that enhances mixing efficiency. In addition, injecting the hydrogen peroxide 16 in the opposite flow direction to the flow of sulfuric acid 14 (i.e., counter-flow) creates a disturbance in the flow that aids in uniform mixing.

FIG. 3A also illustrates the relatively short mixing distance 30 required to mix the hydrogen peroxide 16 into the sulfuric acid 14, compared to the more conventional t-junction type nozzle 22 in FIG. 2B. FIG. 3B illustrates improved mixing performance as compared to FIG. 2A. In this embodiment, the hydrogen peroxide 16 is injected coaxial to, and in the opposite direction of, the flow of the sulfuric acid 14. The interaction between the dissimilar fluid directions and densities, results in enhanced turbulence and roiling within the mixing zone 24. When hydrogen peroxide 16 is centrally injected in a direction opposite the flow of sulfuric acid 14, the SPM mixing ratio has less impact on mixing performance as compared to other orientations. The injection tube length 21 may be varied to establish a mixing zone 24 at any desired location in the delivery system 26, which will also vary the mixing distance 30, which is the distance from the nozzle exit 23 to the outlet 18. The injection tube length from the point of penetration into the process chemical delivery system 26 to the nozzle exit 23 may be from 25 to 35 mm, for example. By way of further example, the mixing distance 30 may be 50 mm or less, or may be 10 mm or less. While the configuration of this embodiment introduces the hydrogen peroxide 16 in a flow direction that differs from the flow direction of the sulfuric acid 14, it should be noted that same-direction flow mixing may be suitable for certain applications.

The design of the nozzle 22 in this embodiment is also compatible for efficient dispensing of the SPM onto a rotating silicon wafer. For the sake of clarity, the disclosed embodiments show the intermixing of two substances. However, a plurality of substances, supplied at various pressures and flow volumes, may also be used.

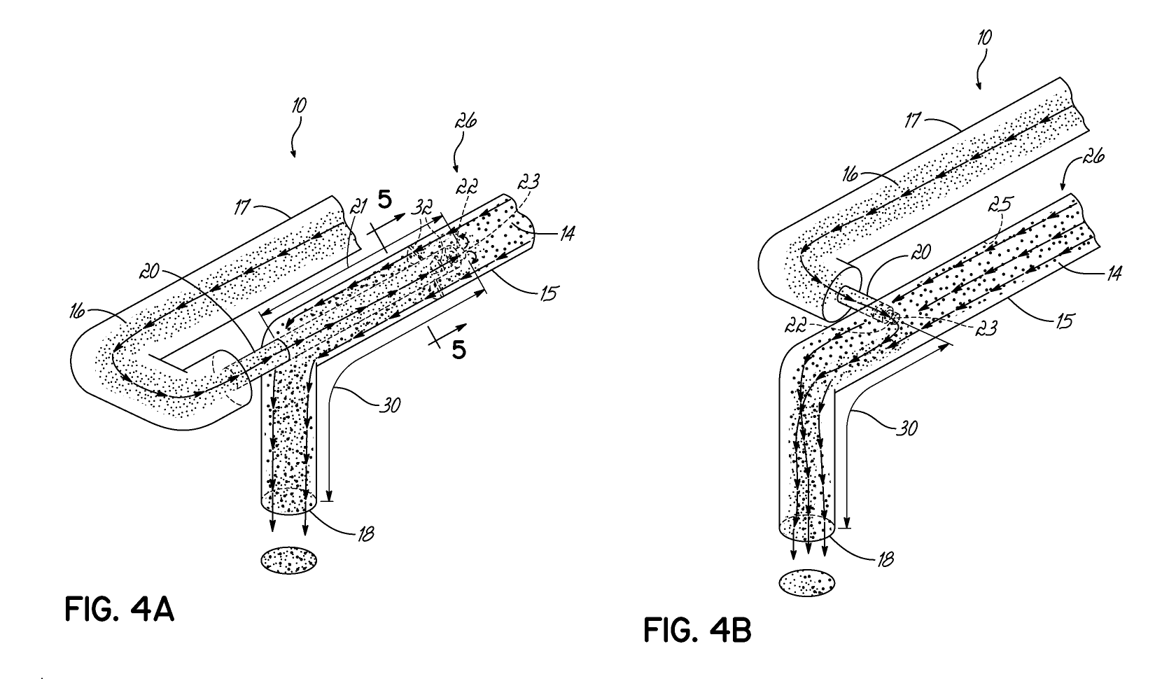

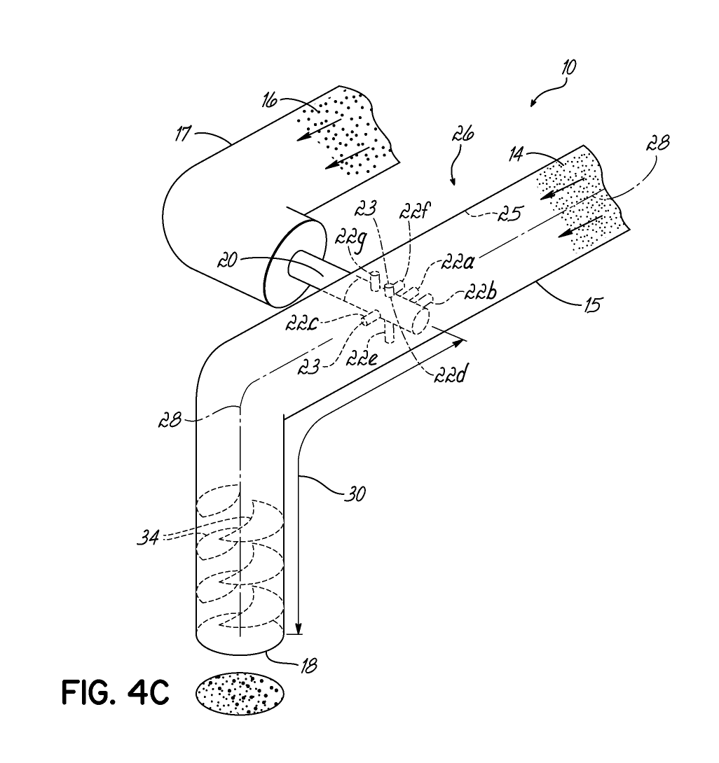

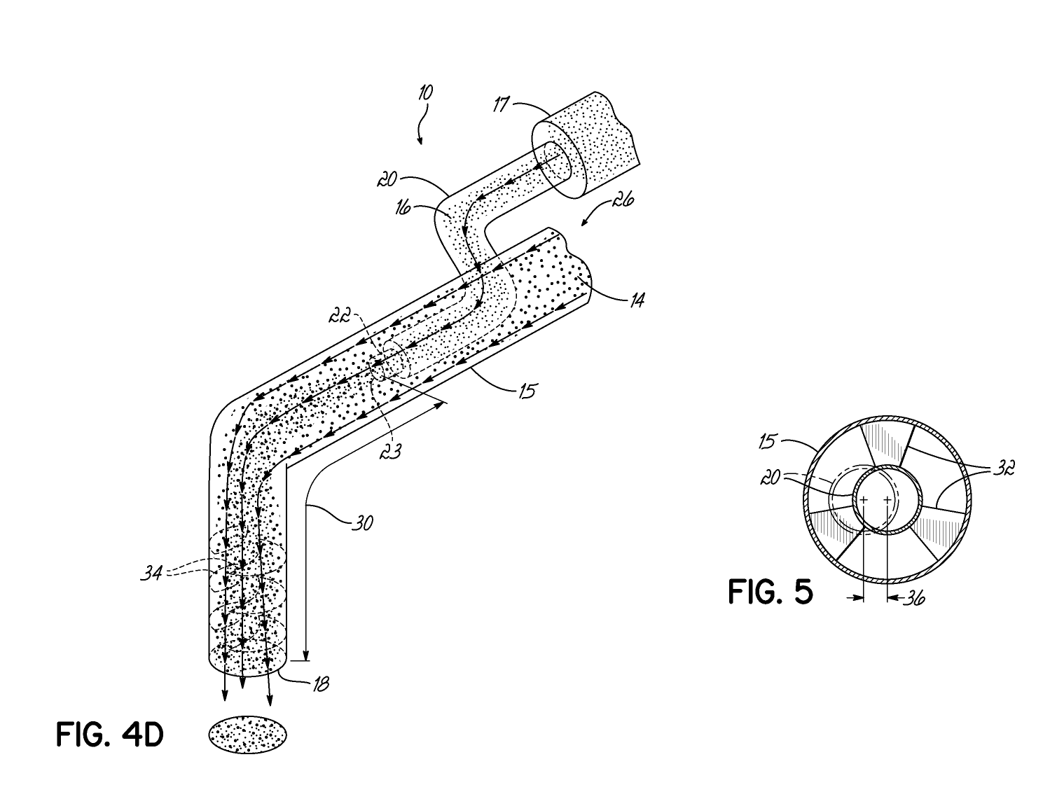

The descriptions of embodiments below are related to the drawings in FIG. 4A to 4D and in FIG. 5. FIG. 4A shows a perspective view substantially similar to the configuration found in FIG. 3A. The injection tube 20 and nozzle 22 are coaxial to the sulfuric acid 14, and serve to introduce hydrogen peroxide 16 in a direction opposite the flow of sulfuric acid 14. The distance from the nozzle exit 23 of the nozzle 22 to the outlet 18 may be referred to as the mixing distance 30. The mixing distance 30 may be adjusted to ensure that sufficient mixing has occurred by the time the combined fluids have reached the outlet 18. Since the mixing distance 30 may be constrained by certain criteria, for example a fluid system must often physically fit within a chamber of a processing tool, the improved mixing performance of the disclosed invention may advantageously reduce the required mixing distance 30. In embodiments wherein the injection tube 20 is not parallel to the flow of the sulfuric acid 14, for example non-parallel embodiments are shown at FIG. 4B and FIG. 4C, varying the location of the injection tube 20 along the process chemical delivery system 26 changes the mixing distance 30. Thus, system parameters are selected to produce uniform mixing of the sulfuric acid 14 and hydrogen peroxide 16 within a target mixing distance and time.

Under certain operating conditions, fluid forces and reaction temperatures may result in distortion or damage to the injection tube 20. Therefore, support mechanisms 32 may be utilized to provide additional structural reinforcement to the injection tube 20. The support mechanism 32 may include fins or ribs that extend radially from the injection tube 20. These fins may be configured to support the injection tube 20 by contacting the interior wall 25 of the process chemical delivery system 26, either at discrete locations, or continuously along the length of the injection tube 20. In the alternative, the support mechanism 32, by utilizing fins, longitudinal flutes, or other stiffening members, may provide enhanced rigidity to the injection tube 20 without contacting the interior wall 25 of the process chemical delivery system 26. The support mechanism 32 may be designed to advantageously increase turbulence, thus improving mixing efficiency.

FIG. 4B illustrates a non-coaxial center injection configuration. Here, the direction of the injection tube 20 is substantially perpendicular to the flow of the sulfuric acid 14, but it is directed at a region of the sulfuric acid 14 flow that differs from a traditional t-junction. Unlike the t-junction, here, the nozzle 22 is oriented away from the interior wall 25 of the process chemical delivery system 26. As one of ordinary skill in the art will recognize, a non-perpendicular angle of approach may also be utilized in certain circumstances. The location and orientation of the nozzle 22 may be adjusted several different ways. In one embodiment, the injection tube 20 may penetrate the wall of the process chemical delivery system 26 and terminate in a nozzle 22 directed at the center 28, or some other portion, of the sulfuric acid 14 flow.

Alternatively, as seen in FIG. 4C, the injection tube 20 may completely traverse the width of the process chemical delivery system 26 and terminate in a closed end. One or more nozzles 22a-22g are positioned along the injection tube 20 within the sulfuric acid fluid line 15. Note, in this view, fluid flow and stippling have been truncated near their source to more clearly depict the configuration of the nozzles 22a-22g. To accommodate a variety of injection orientations, a nozzle 22a may be situated at the midpoint of the traversing injection tube 20 segment substantially at the center 28 of the flow stream, or at some distance from the midpoint, such as for nozzle 22b. For center coaxial injection, the nozzle 22a and/or a nozzle 22c may be utilized for counter-flow or same-direction-flow, respectively. If a sufficiently thin injection tube 20 and sufficiently short nozzle 22d are selected, nozzle 22d may be disposed at any point along the circumference of the midpoint of the injection tube 20, while still substantially dispensing into the center 28 of the sulfuric acid 14 flow. Nozzle 22d may be perpendicular to the direction of flow or may be at any non-parallel angle, whereby the hydrogen peroxide traverses, at least partially, the flow of the sulfuric acid, thereby creating turbulence to augment the mixing action. Angles that are closer to perpendicular or angled against the direction of flow create more turbulence than angles that are closer to parallel or angled with the direction of flow. Angled nozzles 22g may also be provided at an offset distance from the center 28, for example, at an offset of 0.4 mm or less. Additionally, by extending the length of any angled nozzle, such as nozzle 22e, injection may be further accomplished at substantially non-center locations, to include the bottom or the side of the process chemical delivery system 26, i.e., perimeter portions of the flow stream. Additionally, a plurality of nozzles, for example 22a, 22b, and 22f may simultaneously direct the hydrogen peroxide 16 in an opposite direction with respect to the flow of sulfuric acid 14, including a center coaxial point with nozzle 22a and offset points with nozzles 22b and 22f. By way of example and not limitation, the offset nozzles 22b, 22f may be offset from the center 28 by 0.4 mm or less. Alternatively and by way of example, hydrogen peroxide 16 may be injected in a plurality of different directions with respect to the flow of sulfuric acid 14, by simultaneously utilizing nozzles 22a, 22e. Further, hydrogen peroxide 16 may be injected in a plurality of different directions by using sets of nozzles. For example, this can be performed by simultaneously activating one set of nozzles 22a, 22b, and 22f while dispensing from another set of nozzles 22d and 22g. Thus, any plurality of nozzles may be used to inject the hydrogen peroxide 16 in the desired locations and directions with respect to the flow of the sulfuric acid 14.

Static mixing elements 34 may be included downstream of the nozzles 22a-22g along the mixing distance 30 at one or more locations to augment the mixing action, as will be discussed in further detail below in the discussion of FIG. 4D.

FIG. 4D depicts a configuration, wherein coaxial injection is accomplished with both sulfuric acid 14 and hydrogen peroxide 16 traveling in the same direction. In the event that the injection tube 20 fails to generate sufficient mixing turbulence, static mixing elements 34 may be added to augment the mixing action. The static mixing elements 34 force the fluid to follow convoluted paths, and thus improve rapid mixing. These static mixing elements 34 may include twisting structures, angular projections, perforations, or other effective mixing geometries known to the art. The static mixing elements 34 provide improved mixing performance, and reduced mixing distance 30, when added to any of the embodiments described above.

While earlier discussed embodiments have contemplated injecting hydrogen peroxide 16 at some distance away from the center 28 of the flow, FIG. 5 is included to depict the geometry more clearly. The deviation of the injection tube 20 from the center 28 of the flow of sulfuric acid 14 may be referred to as the offset 36. FIG. 5 shows the offset 36 as applied to one of the coaxial configurations of FIG. 3A, 4A, and 4D. Likewise, offset 36 may be applied to the configurations of FIG. 4B or 4C by orienting the nozzle or nozzles 22 in substantially any position other than 22a or 22c.

While sulfuric acid 14 and hydrogen peroxide 16 have been used to describe the embodiments above, many types of process chemicals may benefit from the disclosed embodiments. Thus, the invention is applicable to injecting a second process chemical into the flow of a first process chemical to achieve uniform mixing of the first and second process chemicals quickly and efficiently before exiting a delivery system into a processing chamber. The invention is particularly useful where the first and second process chemicals react to form reaction products, but may also be applicable to carrier gases and diluents.

In one embodiment of a method of the invention for rapidly mixing process chemicals to generate a treatment liquid for processing a single substrate, the method comprises flowing a first process chemical in a process chemical delivery system with a first direction of flow having a center axis, and injecting a second process chemical from a nozzle into the flow of the first process chemical in the process chemical delivery system to effect a mixing of the first process chemical with the second process chemical to form a treatment liquid. The nozzle is oriented at or near the center axis to produce uniformity in the mixing of the first and second process chemicals within a target mixing distance between the nozzle and an outlet of the process chemical delivery system and within a target mixing time. By “at or near the center axis” is meant that the injection occurs primarily within a central portion of the stream of the first process chemical, and is not injected solely at the perimeter of the stream where uniformity is least likely to be achieved. By way of example and not limitation, an offset from the center axis may be 0.4 mm or less.

By way of example, the target mixing distance may be 50 mm or less, or may be 10 mm or less. By way of example, the target mixing time may be 2 ms or less. The first process chemical may be an acid and the second process chemical may be an oxidizer, for example sulfuric acid and hydrogen peroxide, respectively. The sulfuric acid may be a 98 weight percent solution and the hydrogen peroxide may be a 30 weight percent solution. In one embodiment, a mixing ratio or efficiency of sulfuric acid solution to the hydrogen peroxide solution is optimized to the lowest value of a hydrogen peroxide metric at the nozzle exit. For example, the hydrogen peroxide metric is hydrogen mass fraction at the nozzle exit.

In a further embodiment, the nozzle includes a plurality of nozzles for injecting the second process chemical into more than one location in the flow of the first process chemical and/or in more than one direction. For example, one nozzle may inject the first process chemical coaxially with the center axis in an opposite direction to the flow of the first process chemical (e.g., nozzle 22a); one nozzle may inject the first process chemical coaxially with the center axis in the same direction to the flow of the first process chemical (e.g., nozzle 22c); one nozzle may inject the first process chemical at an offset distance to the center axis in an opposite direction to the flow of the first process chemical (e.g., nozzles 22b and 22f); one nozzle may inject the first process chemical at an offset distance to the center axis in the same direction to the flow of the first process chemical; one nozzle may inject the first process chemical at an angle from the center axis, such as a perpendicular angle, to traverse the direction of the flow of the first process chemical (e.g., nozzle 22d); and one nozzle may inject the first process chemical at an offset distance and angle from the center axis to traverse the direction of the flow of the first process chemical (e.g., nozzle 22g). Any one or combination of these nozzles may be used to inject the second process chemical at or near the center axis. One or more additional nozzles may be used to inject the second process chemical in perimeter locations within the process chemical delivery system (e.g., nozzle 22e) to supplement the central injection. Injection at an angle to the center axis may be any non-parallel angle, for example perpendicular, less than 90 degrees, or greater than 90 degrees, so as to at least partially traverse the direction of flow, and thereby create a turbulent action that facilitates mixing.

The method may further include dispensing the treatment liquid onto a portion of a surface of the substrate. The first process chemical may be sulfuric acid and the second process chemical may be hydrogen peroxide, and the substrate may comprise a layer of a high dose implant resist strip, wherein the method uniformly mixes the sulfuric acid and hydrogen peroxide to create reaction products that efficiently strip the high dose implant resist strip.

In one embodiment of a system of the invention for mixing process chemicals to optimize resist strip performance, the system comprises a process chamber containing a single substrate, where the substrate has a high dose ion implant resist strip and the process chamber is configured to strip the resist, and a process chemical delivery system configured to deliver a treatment liquid comprising a first process chemical, a second process chemical, and reaction products of the first and second process chemicals from an outlet onto a portion of the surface of the substrate. The process chemical delivery system comprises a first process chemical supply line configured to deliver the first process chemical at a first temperature, a first flow rate, and a first direction of flow, and a second process chemical supply line configured to deliver the second process chemical at a second temperature and a second flow rate, the second process chemical supply line having an injection tube with a nozzle arrangement that includes at least one nozzle positioned to inject the second process chemical in the center of flow of the first process chemical in the first process chemical supply line. The first process chemical supply line, the second process chemical supply line, and the nozzle arrangement are operably configured to complete uniform mixing of the first and second process chemicals within the first process chemical supply line along a target mixing distance between the nozzle arrangement and the outlet and within a target mixing time.

In one embodiment, the nozzle arrangement includes a plurality of nozzles coupled to the injection tube, wherein the plurality of nozzles includes at least two nozzles positioned at different locations to inject the second process chemical in two different positions or directions relative to the direction of flow. In another embodiment, the second process chemical supply line includes a plurality of injection tubes each with a nozzle arrangement, at least one of which includes the at least one nozzle positioned to inject the second process chemical in the center of flow of the first process chemical, and wherein the plurality of injection tubes enter the process chemical delivery system at different locations along the direction of flow to inject the second process chemical in two different positions or directions relative to the direction of flow. The system may further include a support mechanism on the injection tube or tubes sufficient to prevent bending thereof within the first process chemical supply line.

In accordance with another method of the invention for rapidly mixing process chemicals to generate a treatment liquid for stripping a resist layer on a single substrate, the method includes flowing a first process chemical in a first process chemical delivery system, where the first process chemical delivery system has a first direction of flow, a center of the flow, and a first mixing zone, and the first process chemical has a first chemical temperature and a first chemical concentration. The method further includes injecting a second process chemical into the first mixing zone of the first process chemical delivery system using a nozzle, where the second process chemical has a second process chemical temperature and a second process chemical concentration, and the injection of the second process chemical is at a second direction of flow. The method further includes mixing the first process chemical with the second process chemical, and causing a reaction of the first process chemical and the second process chemical to create reaction products, where the first process chemical, the second process chemical, and the reaction products form a treatment liquid. The injection of the second process chemical is operably designed to produce uniform mixing of the first and second process chemicals within a target mixing distance in the first mixing zone of the first process chemical delivery system and within a target mixing time.

In accordance with another system of the invention for mixing of process chemicals to optimize resist strip performance, the system includes a process chamber containing a single substrate, the substrate having a resist layer, the resist layer being a high dose ion implant resist strip, and the process chamber configured to strip the resist layer. The system further includes a process chemical delivery system configured to deliver a treatment liquid comprising a first process chemical, a second process chemical, and reaction products of the first and second process chemicals onto a portion of the surface of the substrate. The process chemical delivery system includes a first process chemical supply line configured to deliver the first process chemical at a first temperature, a first flow rate, and a first direction of flow; and a second process chemical supply line configured to deliver the second process chemical at a second temperature and a second flow rate. The delivery of the second process chemical is performed using a nozzle to inject the second process chemical in the center of flow of the first process chemical in the first process chemical supply line in the opposite direction of flow as the first process chemical supply line, the nozzle having a mixing zone of the first and second process chemicals. The delivery of the second process chemical is operably designed to complete uniform mixing of the first and second process chemicals within a target mixing distance in the mixing zone of the nozzle and within a target mixing time.

While the present invention has been illustrated by the description of one or more embodiments thereof, and while the embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method and illustrative examples shown and described. Accordingly, departures may be made from such details without departing from the scope of the general inventive concept.

What is claimed is:

1. A method of rapidly mixing process chemicals to generate a treatment liquid for processing a single substrate, the method comprising:
flowing a first process chemical in a process chemical delivery system with a direction of flow along a center axis;
injecting a second process chemical from a nozzle into the flow of the first process chemical in the process chemical delivery system to effect a mixing of the first process chemical with the second process chemical to form a treatment liquid,
wherein the nozzle is oriented at or near the center axis to produce uniformity in the mixing of the first and second process chemicals within a target mixing distance between the nozzle and an outlet of the process chemical delivery system and within a target mixing time.

2. The method claim 1 wherein the first process chemical is an acid and the second process chemical is an oxidizer.

3. The method of claim 1 wherein the first process chemical is sulfuric acid and the second process chemical is hydrogen peroxide.

4. The method of claim 3 wherein the target mixing distance is 50 mm or less.

5. The method of claim 3 wherein the target mixing time is 2 ms or less.

6. The method of claim 1 wherein the injection of the second process chemical is coaxial with the center axis in the direction of flow.

7. The method of claim 1 wherein the injection of the second process chemical is coaxial with the center axis in an opposite direction to the direction of flow.

8. The method of claim 1 wherein the injection of the second process chemical is at a non-parallel angle to the center axis of the direction of flow.

9. The method of claim 8 wherein the non-parallel angle is substantially 90 degrees to the center axis of the direction of flow.

10. The method of claim 1 wherein the nozzle includes a plurality of nozzles coupled to an injection tube, wherein the plurality of nozzles includes at least two nozzles positioned at different locations to inject the second process chemical in two different positions or directions relative to the direction of flow.

11. The method of claim 10 wherein at least one of the plurality of nozzles is at a non-parallel angle to the center axis of the direction of flow.

12. The method of claim 10 wherein at least one of the plurality of nozzles is coaxial with the center axis in the direction of flow and wherein mixing of the first process chemical with the second process chemical is facilitated with static mixers positioned downstream of the plurality of nozzles in the process chemical delivery system.

13. The method of claim 10 wherein at least one of the plurality of nozzles is coaxial with the center axis in an opposite direction to the direction of flow.

14. The method of claim 13 wherein at least one of the plurality of nozzles is offset from the center axis and oriented in an opposite direction to the direction of flow.

15. The method of claim 1 further comprising dispensing the treatment liquid onto a portion of a surface of the substrate.

16. The method of claim 15 wherein the first process chemical is sulfuric acid and the second process chemical is hydrogen peroxide, and wherein the substrate comprises a layer of a high dose implant resist strip.

17. A system for mixing of process chemicals to optimize resist strip performance, the system comprising:
a process chamber containing a single substrate, the substrate having a resist layer, the resist layer being a high dose ion implant resist strip, the process chamber configured to strip the resist layer;
a process chemical delivery system configured to deliver a treatment liquid comprising a first process chemical, a second process chemical, and reaction products of the first and second process chemicals from an outlet onto a portion of the surface of the substrate, the process chemical delivery system comprising:
a first process chemical supply line configured to deliver the first process chemical at a first temperature, a first flow rate, and a first direction of flow; and
a second process chemical supply line configured to deliver the second process chemical at a second temperature and a second flow rate, the second process chemical supply line having an injection tube with a nozzle arrangement that includes at least one nozzle positioned to inject the second process chemical in the center of flow of the first process chemical in the first process chemical supply line,
wherein the first process chemical supply line, the second process chemical supply line, and the nozzle arrangement are operably configured to complete uniform mixing of the first and second process chemicals within the first process chemical supply line along a target mixing distance between the nozzle arrangement and the outlet and within a target mixing time.

18. The system of claim 17 wherein the nozzle arrangement includes a plurality of nozzles coupled to the injection tube, wherein the plurality of nozzles includes at least two nozzles positioned at different locations to inject the second process chemical in two different positions or directions relative to the direction of flow.

19. The system of claim 17 further comprising a support mechanism on the injection tube sufficient to prevent bending of the injection tube within the first process chemical supply line.
